(19) United States
(12) Patent Application Publication
(10) Pub. No.: US 2026/0120789 A1
(43) Pub. Date: Apr. 30, 2026

(54) CONTENT ADDRESSABLE MEMORY LOADING IN SEMICONDUCTOR DEVICES

(71) Applicant: Yangtze Memory Technologies Co., Ltd., Wuhan (CN)

(72) Inventor: Chong JIN, Wuhan (CN)

(21) Appl. No.: 18/947,874

(22) Filed: Nov. 14, 2024

(30) Foreign Application Priority Data
Oct. 29, 2024 (CN) 202411525523.8

(51) Int. Cl. G11C 29/00

(52) U.S. Cl. CPC G11C 29/783; G11C 29/781; G11C 29/822

(57) ABSTRACT

Methods, devices, and systems for content addressable memory (CAM) loading in semiconductor devices are provided. In one aspect, an example memory device includes a memory array and a peripheral circuit coupled to the memory array. The peripheral circuit includes CAMs, a data path, and a buffer circuit coupled to the CAMs through the data path. The buffer circuit includes a multiplexer coupled to a storage unit and a command/address (CA) interface. The multiplexer is configured to dynamically select either the storage unit or the CA interface.

### CROSS-REFERENCE TO RELATED APPLICATIONS

This application claims priority to Chinese Patent Application No. 202411525523.8, filed on Oct. 29, 2024, which is hereby incorporated by reference in its entirety.

### TECHNICAL FIELD

The present disclosure relates to semiconductor devices, e.g., memory devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure relates to content addressable memory (CAM) loading in semiconductor devices.

One aspect of the present disclosure features a memory device including a memory array and a peripheral circuit coupled to the memory array. The memory array includes memory banks. The peripheral circuit includes CAMs, a data path, and a buffer circuit coupled to the CAMs through the data path. The buffer circuit includes a multiplexer coupled to a storage unit and a command/address (CA) interface, and the multiplexer is configured to select either the storage unit or the CA interface.

In some implementations, the buffer circuit further includes a buffer coupled between the data path and the multiplexer, and the multiplexer includes a first input coupled to the CA interface, a second input coupled to the storage unit, and an output coupled to the buffer.

In some implementations, the multiplexer is coupled to the CA interface through a control circuit, and the control circuit includes an address and bank decoder and a control logic including a command decoder.

In some implementations, the storage unit is a one-time programmable (OTP) memory configured to store defective row addresses.

In some implementations, the CAMs are in a row address decoder of the peripheral circuit.

In some implementations, the peripheral circuit further includes a shift register coupled to the CAMs.

In some implementations, the shift register includes multiple bit storage units. Each of the multiple bit storage units is coupled to a respective CAM of the CAMs and is configured to enable writing data into the respective CAM.

In some implementations, the CAMs are coupled to the shift register through CAM selection lines.

In some implementations, the memory device is a dynamic random access memory (DRAM) device, and at least one memory bank of the memory banks includes DRAM cells.

In some implementations, the peripheral circuit is configured to load data from the storage unit to the CAMs in a power on reset process of the memory device.

In some implementations, the peripheral circuit further includes a match circuit coupled between the data path and the CAMs, and the match circuit includes comparator circuits and is configured to, in response to receiving an address from the CA interface, compare the address to the data loaded to the CAMs and generate a comparison result.

One aspect of the present disclosure features a method of operating a memory device. The method includes loading, by a peripheral circuit of the memory device, data from a storage unit to CAMs through a buffer circuit and a data path. The peripheral circuit includes the CAMs, the buffer circuit, and the data path. The buffer circuit includes a multiplexer coupled to the storage unit. The method further includes receiving, by the peripheral circuit, an address from a CA interface through the buffer circuit and the data path. The CA interface is coupled to the multiplexer.

In some implementations, the method further includes comparing the address to the data loaded to the CAMs.

In some implementations, loading the data from the storage unit to the CAMs includes: controlling a shift register coupled to the CAMs to enable writing of a first CAM of the CAMs; loading a first portion of the data from the storage unit to the first CAM; controlling the shift register to enable writing of a second CAM of the CAMs; and loading a second portion of the data from the storage unit to the second CAM.

In some implementations, loading the data from the storage unit to the CAMs includes controlling the multiplexer to select the storage unit and forward the data from the storage unit to the data path.

In some implementations, loading the data from the storage unit to the CAMs includes loading the data from the storage unit to the CAMs in a power on reset process of the memory device.

In some implementations, receiving the address from the CA interface includes controlling the multiplexer to select the CA interface and forward the address to the data path.

In some implementations, receiving the address from the CA interface includes receiving the address from the CA interface after a power on reset process of the memory device.

In some implementations, the storage unit is an OTP memory configured to store defective row addresses.

One aspect of the present disclosure features a memory system. The memory system includes a memory device and a memory controller coupled to the memory device. The memory device includes a memory array including memory banks; and a peripheral circuit coupled to the memory array. The peripheral circuit includes CAMs, a data path, and a buffer circuit coupled to the CAMs through the data path. The buffer circuit includes a multiplexer coupled to a storage unit and a CA interface. The multiplexer is configured to select either the storage unit or the CA interface.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices.

FIG. 2 illustrates a schematic diagram of an example memory device including a peripheral circuit and an array of memory cells each having a vertical transistor.

FIG. 3 illustrates memory device having a memory array and an example peripheral circuit.

FIG. 4 illustrates an example peripheral circuit.

FIGS. 5A-5B illustrate other example peripheral circuits.

FIG. 6 is a schematic diagram illustrating an example row content addressable memory (CAM) coupled to a data path.

FIG. 7 is a schematic timing diagram showing an example method of writing data to a CAM.

FIG. 8 illustrates a flow chart of an example process of operating a memory device.

Like reference numbers and designations in the various drawings indicate like elements. It is also to be understood that the various exemplary implementations shown in the figures are merely illustrative representations and are not necessarily drawn to scale.

### DETAILED DESCRIPTION

The present disclosure relates to semiconductor devices, specifically addressing the inefficiencies in resource utilization associated with row redundancy circuits in memory devices. Row redundancy circuits are employed in memory devices (e.g., dynamic random access memory (DRAM)) to replace defective rows with spare redundancy rows, thereby enhancing the overall yield of the production of the memory devices. In some implementations, during a power on reset (POR) process, the row content addressable memory (CAM) is programmed with the addresses of defective rows stored in a storage unit (e.g., an anti-fuse memory). Given a typically large size of the row address bit field, a significant number of registers and latches are required to store this address information, necessitating extensive metal routing for data transfer. However, after the POR process, these resources, including the routing and shift registers utilized for row CAM loading, remain largely unused, leading to inefficient resource usage.

The present disclosure provides techniques that enable a memory device to reuse a data path coupled to CAMs in the memory device, thereby reduces the routing complexity. In some implementations, the memory device includes a memory array and a peripheral circuit coupled to the memory array. The peripheral circuit includes CAMs, a data path, and a buffer circuit coupled to the CAMs through the data path. The buffer circuit includes a multiplexer coupled to a storage unit and a command/address (CA) interface. The multiplexer is configured to dynamically select either the storage unit or the CA interface.

Implementations of the present disclosure can provide one or more of the following technical advantages, particularly in terms of resource efficiency and overall device size. First, by integrating a multiplexer to the data path, the described techniques allow dynamic selection between loading data into the CAMs and reading data stored in the CAMs to compare the stored data with an address from the CA interface, thereby adding versatility and efficiency to the data management process. Second, a shift register used for data storage is eliminated. Instead, a shift register is employed to store a CAM selection signal, simplifying the data flow and further reducing the routing overhead. Third, the streamlined approach described in the present disclosure, facilitated by the buffer circuit including the multiplexer, can enable the orderly data writing to the CAMs, thereby leading to a more efficient memory operation. Additionally, the proposed row CAM loading method is compatible with various loading techniques and thus can offer flexibility in design. The efficient use of routing and circuit components ensures that the system remains versatile and adaptable to different row redundancy circuits.

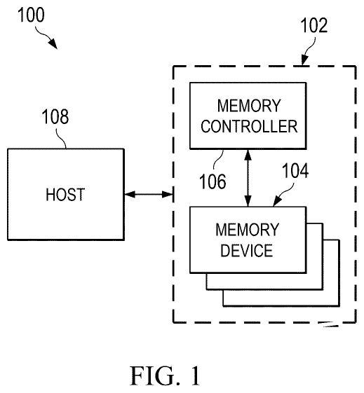

FIG. 1 illustrates a block diagram of an example system 100 having one or more semiconductor devices (e.g., memory devices), according to some aspects of the present disclosure. The system 100 can be a mobile phone, a desktop computer, a laptop computer, a tablet, a server, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include a host 108 and a memory system 102 having one or more memory devices 104 and a memory controller 106. Host 108 can include a processor of an electronic device, such as a central processing unit (CPU), or a system-on-chip (SoC), such as an application processor (AP). Host 108 can be configured to send or receive data to or from the one or more memory devices 104.

A memory device 104 can be any memory device disclosed herein. In some implementations, the memory device 104 includes a DRAM memory. Memory controller 106 (a.k.a., a controller circuit) is coupled to memory device 104 and host 108. Consistent with implementations of the present disclosure, memory device 104 can include a plurality of conductive interconnections through a cover layer that are in contact with conductive pads in a conductive pad layer, and memory controller 106 can be coupled to memory device 104 through at least one of the plurality of conductive interconnections. Memory controller 106 is configured to control memory device 104. Memory controller 106 can manage data stored in memory device 104 and communicate with host 108.

In some implementations, memory controller 106 can be configured to control operations of memory device 104, such as read, program (or write) operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, formatting memory device 104.

Memory controller 106 can communicate with an external device (e.g., host 108) according to a particular communication protocol. For example, memory controller 106 may communicate with the external device through at least one of various interface protocols, such as a USB protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

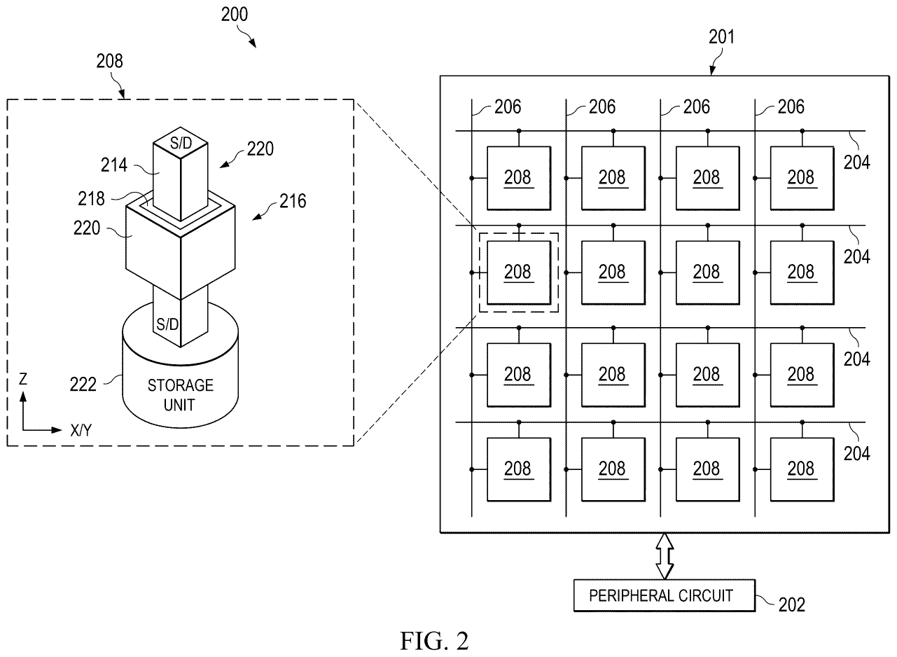

FIG. 2 illustrates a schematic diagram of a memory device 200 including peripheral circuits and an array of memory cells each having a vertical transistor, according to some aspects of the present disclosure. Memory device 200 can include a memory array 201 and peripheral circuits 202 coupled to memory array 201. Memory array 201 can be any suitable memory array in which each memory cell 208 includes a vertical transistor 210 and a storage unit 212 coupled to vertical transistor 210. In some implementations, memory array 201 is a DRAM cell array, and storage unit 212 is a capacitor for storing charge as the binary information stored by the respective DRAM cell. In some implementations, memory array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory array 201 for controlling the switch of vertical transistors 210 in memory cells 208 located in a row, as well as bit lines 206 coupling peripheral circuits 202 and memory array 201 for sending data to and/or receiving data from memory cells 208 located in a column. That is, each word line 204 is coupled to a respective row of memory cells 208, and each bit line is coupled to a respective column of memory cells 208.

Consistent with the scope of the present disclosure, vertical transistors 210, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity, as described below in detail. As shown in FIG. 2, in some implementations, different from planar transistors in which the active regions are formed in the substrates, vertical transistor 210 includes a semiconductor body 214 extending vertically (in the Z-direction) above the substrate (not shown). That is, semiconductor body 214 can extend above the top surface of the substrate to allow channels to be formed not only at the top surface of semiconductor body 214, but also at one or more side surfaces thereof. As shown in FIG. 2, for example, semiconductor body 214 can have a cuboid shape to expose four sides thereof. It is understood that semiconductor body 214 may have any suitable 3D shape, such as polyhedron shapes or a cylinder shape. That is, the cross-section of semiconductor body 214 in the plan view (e.g., in the X-Y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered as having multiple sides, such that the gate structures is in contact with more than one side of the semiconductor bodies. As described below with respect to the fabrication process, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2, vertical transistor 210 can also include a gate structure 216 in contact with one or more sides of semiconductor body 214, e.g., in one or more planes of the side surface(s) of the active region. In other words, the active region of vertical transistor 210, e.g., semiconductor body 214, can be at least partially surrounded by gate structure 216. Gate structure 216 can include a gate dielectric 218 over one or more sides of semiconductor body 214, e.g., in contact with four side surfaces of semiconductor body 214, as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, which is a form of gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, which is a form of a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the Z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the Z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2, can have a larger gate control area to achieve better channel control with a smaller subthreshold swing. Since the channel is fully depleted, the leakage current (Ioff) of vertical transistor 210 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors as described below in detail. That is, gate structure 216 may be in contact with a single side of semiconductor body 214, for example, for the purpose of increasing the transistor and memory cell density. It is also understood that although gate dielectric 218 is shown as being separate (a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the X-Y plane), and the source and the drain are disposed at different locations in the same lateral plane (the X-Y plane). In contrast, in vertical transistor 210, semiconductor body 214 extends vertically (in the Z-direction), and the source and the drain are disposed in the different lateral planes, according to some implementations. In some implementations, the source and the drain are formed at two ends of semiconductor body 214 in the vertical direction (the Z-direction), respectively, thereby being overlapped in the plan view. As a result, the area (in the X-Y plane) occupied by vertical transistor 210 can be reduced compared with planar transistors and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210.

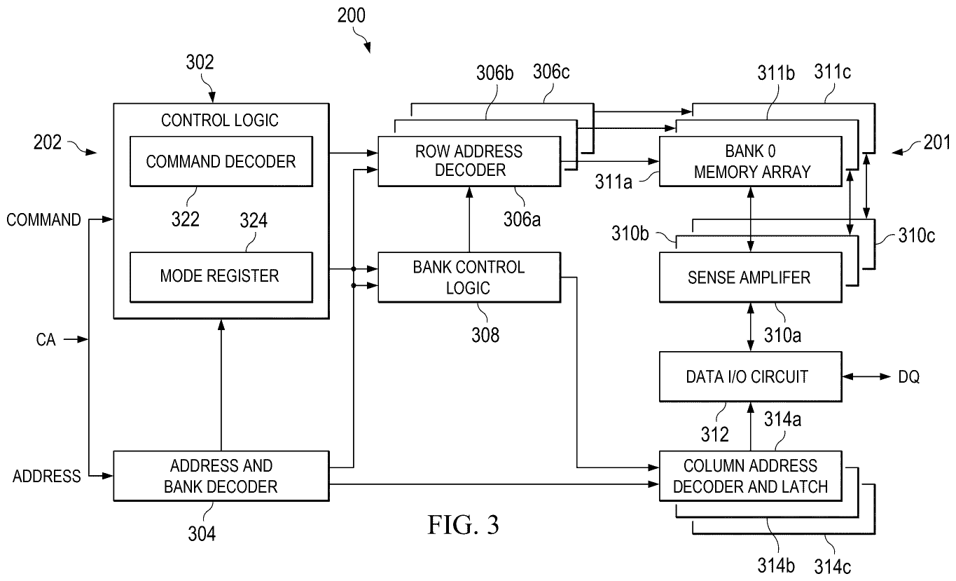

FIG. 3 illustrates memory device having a memory array 201 and an example peripheral circuit 202, according to some aspects of the present disclosure. The peripheral circuit 202 can be coupled to the memory array 201 through bit lines 206 and word lines 204. The peripheral circuit 202 can include any suitable analog, digital, and mixed-signal circuits for facilitating the operations of the memory array 201. The peripheral circuit2 202 can include various types of peripheral circuits formed using metal-oxide-semiconductor (MOS) technologies. The example peripheral circuit 202 include control logic 302, an address and bank decoder 304, a row address decoder 306 (which can also be referred to as a row address decoder and latch), bank control logic 308, a sense amplifier 310, a data input/output (I/O) circuit 312, and a column address decoder and latch 314. In some examples, additional peripheral circuits not shown in FIG. 3 may be included as well.

In some implementations, the memory array 201 can include a number of memory banks 311. Each memory bank 311 can include memory cells 208 arranged in rows and in columns. Memory banks 311 can be accessed and operated independently from one another. As an example in FIG. 3, the memory array 201 includes three memory banks 311a, 311b, 311c. In other examples, the memory array 201 can include other numbers of memory banks. In some implementations, each memory bank 311a, 311b, 311c can be controlled by a corresponding row address decoder 306a, 306b, 306c, a corresponding sense amplifier 310a, 310b, 310c, and a corresponding column address decoder and latch 314a, 314b, 314c.

In some implementations, the memory banks can be arranged into bank groups, for example, to facilitate parallel operation of accessing memory banks 311 in different bank groups at the same time. For example, each bank group can include N memory banks 311, and the nth memory bank in different bank groups can be accessed at the same time (e.g., during a read or a write operation).

The control logic 302 can be configured to control operations of other circuits in the peripheral circuit 202. The control logic 302 can include a command decoder 322 configured to decode commands received by the memory device 200 (e.g., from the memory controller 106), and generate instructions to be sent to other circuits such as bank control logic 308 and the row address decoder 306. The control logic can also include a number of registers, such as mode registers 324 that store information such of configuration parameters, circuit status, pre-set data pattern, etc. Different mode registers 324, or different sets of mode registers 324, may be designated for different uses.

The address and bank decoder 304 can be configured to decode address signals received from the memory controller. The address and bank decoder 304 can send row addresses, column addresses, and signals indicating selected memory banks decoded from the address signals to the row address decoder 306, the column address decoder and latch 314, and the bank logic control 308, respectively.

The row address decoder 306 can be configured to decode the row address received from the address and bank decoder 304, and enable a word line connected to a memory cell for data to be written to or to be read from, according to the decoded row address.

The column address decoder and latch 314 can be configured to decode the column address received from the address and bank decoder 304, ad enable a bit line connected to a memory cell for data to be written to or to be read from, according to the decoded row address.

The sense amplifier 310 can sense and amplify data of a memory cell and can store data in the memory cell. The sense amplifier 404 can be implemented by a cross-coupled amplifier connected between a bit line and a complementary bit line, which are included in the memory array 201.

The bank control logic 308 can be configured to control operations on selected memory banks 311, for example, by controlling a row address decoder 306a, 306b, 306c, a column address decoder and latch 314a, 314b, 314c, and/or a sense amplifier 310a, 310b, 310c that correspond to a selected memory bank 311a, 311b, 311c.

The data input/output circuit 312 can write input data to the memory array 201, and can read output data from the memory array 201. The data input/output circuit 312 can include a read latch to temporality hold output data to be read, and a write latch to temporality hold output data to be written. In some implementations, the data input/output circuit 312 can include data masking logic configured to select certain portions of data, for example, by masking invalid data bits and keeping valid data bits in a read or a write operation.

The peripheral circuits may further include a clock circuit for generating a clock signal, a power supply circuit generating or distributing internal voltages by receiving power supply voltages applied from outside thereof, or the like.

In some implementations, memory cells in the memory array 201 are DRAM cells. Since DRAM is volatile, when power is turned off, data stored in the DRAM cells cannot be preserved. For example, data stored in each memory cell can be in an uncertain state of 0 or 1. Therefore, DRAM needs to be initialized when powered is turned on, e.g., before a user accesses the DRAM for read or write operations. In some implementations, the initialization process includes writing pre-set data in the memory array 201, for example, writing all “1”, all “0”, or another data pattern in the memory array 201. In some implementations, one or more mode registers 324 can store the pre-set data, so that the initialization process does not involve sending data across a data bus between the memory controller and the memory device. For example, under a write pattern command under DDR5, the memory device can source the input data from the mode registers 324 that store the pre-set data, instead of sourcing the input data from the data (DQ) lines.

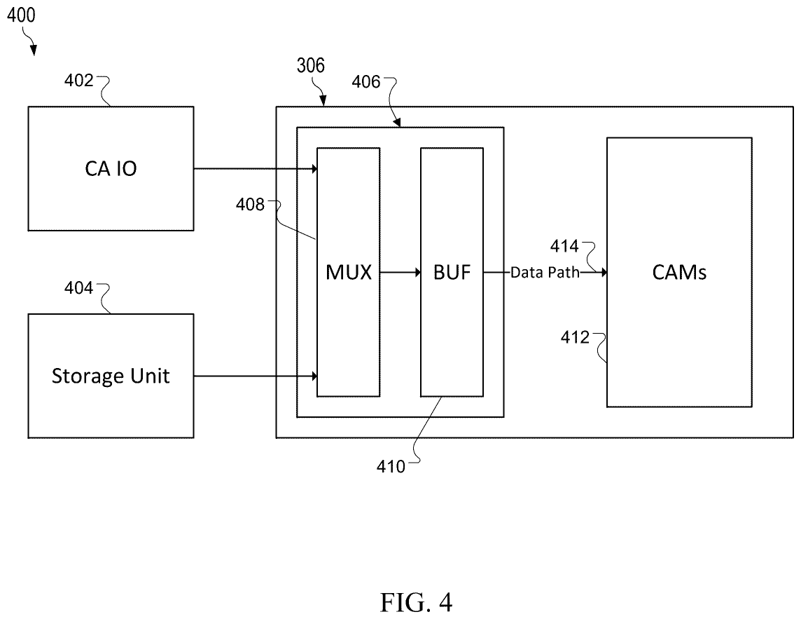

FIG. 4 illustrates an example peripheral circuit 400. The peripheral circuit 400 can be an implementation of the peripheral circuit 202 of FIG. 2 or FIG. 3. As shown in FIG. 4, the peripheral circuit 400 can include the row address decoder 306 (also referred to as a row address decoder and latch). The row address decoder 306 is coupled to a command/address (CA) interface 402 and a storage unit 404. While FIG. 4 illustrates one row address decoder 306 in the peripheral circuit 400, it is understood that the example of FIG. 4 is for illustration purpose and is not intended to be construed in a limiting sense. In some implementations, the peripheral circuit 400 can include multiple row address decoders 306 (e.g., row address decoders 306a, 306b, and 306c as shown in FIG. 3), and each row address decoder 306 can be coupled to a corresponding memory bank (e.g., one of memory banks 311a, 311b, or 311c as shown in FIG. 3).

The row address decoder 306 can include a buffer circuit 406, a data path 414, and one or more content addressable memories (CAMs) 412 coupled to the buffer circuit 406 through the data path 414. The data path 414 can include multiple data lines that can be used to load data stored in the CAMs 412 or transfer data to be written to the CAMs 412. The buffer circuit 406 can include a multiplexer 408 and a buffer 410 coupled to the multiplexer 408. The buffer 410 can be coupled to the data path 414. The multiplexer 408 can be coupled to the storage unit 404 and the CA interface 402. For example, the multiplexer 408 can have a first input coupled to the CA interface 402, a second input coupled to the storage unit 404, and an output coupled to the buffer 410. The multiplexer 408 can be configured to select either the storage unit 404 or the CA interface 402.

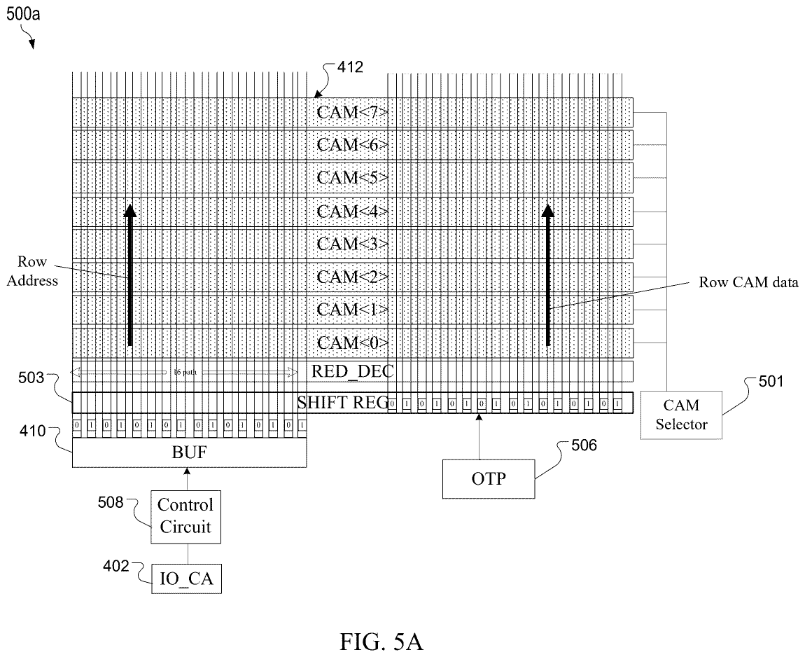

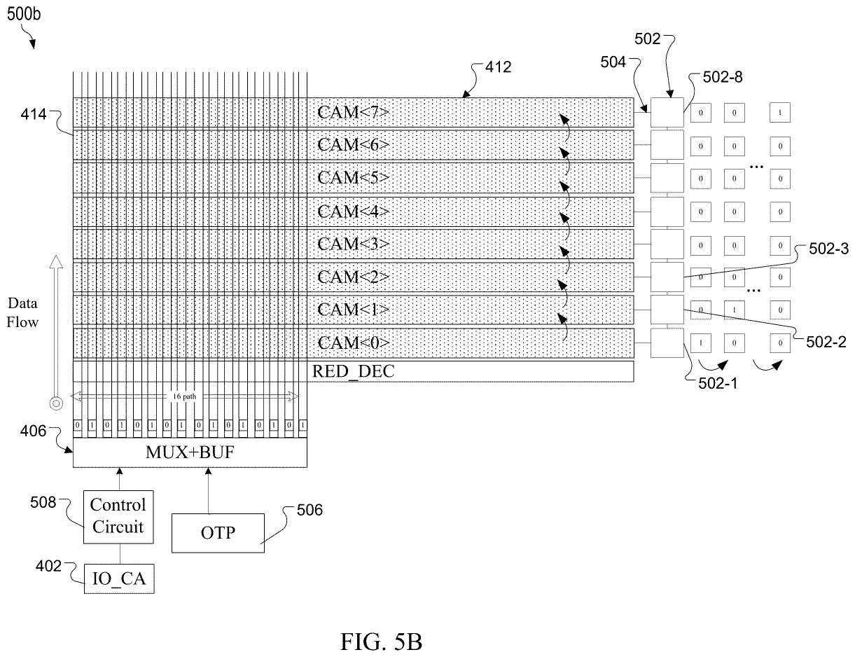

In some implementations, the multiplexer 408 is coupled to the CA interface 402 through a control circuit (e.g., control circuit 508 as shown in FIG. 5B). The control circuit can include an address and bank decoder (e.g., the address and bank decoder 304 of FIG. 3) and a control logic (e.g., the control logic 302 of FIG. 3) including a command decoder (e.g., the command decoder 322 of FIG. 3).

The CAMs 412 can be configured to store addresses. For example, each CAM 412 can be a row CAM and be configured to store an invalid or defective row address (also referred to as a word line address) of a DRAM device (e.g., the memory device 200 of FIG. 2 or FIG. 3). When the CAMs 412 receives an input row address from the CA interface 402, the CAMs 412 can be used to search the input row address in the stored addresses. The CAMs 412 can output a match if the input row address matches an address stored in one of the CAMs 412. In some implementations, data (e.g., the defective row addresses) can be loaded from the storage unit 404 to the CAMs 412 in a power on reset (POR) process of the DRAM device. The storage unit 404 can be any suitable storage unit such as a read-only memory (ROM), a one-time-programmable (OTP) memory, a CAM, a register, or a static random access memory (SRAM). In some implementations, the storage unit 404 can be a non-volatile memory (e.g., an OTP memory) that can retain stored information even after power is removed.

FIG. 5A illustrates an example peripheral circuit 500a. The peripheral circuit 500a can be an implementation of the peripheral circuit 202 of FIG. 2 or the peripheral circuit 400 of FIG. 4. As shown in FIG. 5A, the peripheral circuit 500a can include the CAMs 412, a CAM selector 501, a shift register 503, a buffer 410, a control circuit 508, the CA interface 402, and an OTP memory 506. The OTP memory 506 can be an implementation of the storage unit 404 of FIG. 4 and can be configured to store defective row addresses of a DRAM device. In some implementations, the OTP memory 506 can be an anti-fuse OTP memory. The buffer 410 can be coupled to the CA interface 402 through the control circuit 508. As shown in FIG. 3, the control circuit 508 can include the address and bank decoder 304 and the control logic 302 including the command decoder 322.

In some implementations, during the POR process of the DRAM device, row CAM data (e.g., defective row addresses) can be loaded from the OTP memory 506 to the CAMs 412. For example, the CAM selector 501 can select the row CAMs (e.g., CAM 0, CAM 1, . . . , CAM 7 as shown in FIG. 5A) in the CAMs 412 one by one. When a row CAM is selected, corresponding row CAM data can be transferred from the OTP memory 506 to the shift register 503 and then written from the shift register 503 to the selected row CAM. Next another row CAM can be selected, the shift register 503 can be reset and the above-described operations can be repeated until all row CAMs in the CAMs 412 are loaded. In some implementations, after the POR process of the DRAM device, when the buffer 410 receives a row address from the CA interface 402, the CAMs 412 can compare the received row address to data (e.g., the defective row addresses loaded to the CAMs 412 during the POR process) stored in each of the row CAMs (e.g., CAM 0, CAM 1, . . . , CAM 7) of the CAMs 412. Note that in the example of FIG. 5A, the Cam selector 501 may need many cam selection lines (e.g., metal routings) for selecting certain row CAM, if the CAMs 412 include a large number of row CAMs. In addition, data lines from shift register 503 to each row CAM and the cam selection lines may not be used after row cam load, which can be a waste of resources and chip area.

FIG. 5B illustrates another example peripheral circuit 500b. The peripheral circuit 500b can be an implementation of the peripheral circuit 202 of FIG. 2 or the peripheral circuit 400 of FIG. 4. As shown in FIG. 5B, the peripheral circuit 500b can include the CAMs 412, the data path 414, and the buffer circuit 406. The data path 414 is coupled between the buffer circuit 406 and the CAMs 412. The data path 414 can include multiple data lines. In practice, the data path 414 can be implemented as metal routings between the buffer circuit 406 and the CAMs 412. The buffer circuit 406 (e.g., an input of the multiplexer 408 of the buffer circuit 406) can be coupled to the CA interface 402 through a control circuit 508. As shown in FIG. 3, the control circuit 508 can include the address and bank decoder 304 and the control logic 302 including the command decoder 322. The buffer circuit 406 (e.g., another input of the multiplexer 408 of the buffer circuit 406) can be coupled to an OTP memory 506. The OTP memory 506 can be an implementation of the storage unit 404 of FIG. 4 and can be configured to store defective row addresses of a DRAM device. In some implementations, the OTP memory 506 can be an anti-fuse OTP memory.

The peripheral circuit 500b further includes a CAM selector 502. The CAM selector 502 can be coupled to the CAMs 412 through CAM selection lines 504. In some implementations, as shown in FIG. 5B, the CAM selector 502 can be a shift register. The shift register includes multiple bit storage unit 502-1, 502-2, . . . , 502-8. The CAMs 412 can include multiple row CAMs (e.g., CAM 0, CAM 1, . . . , CAM 7 as shown in FIG. 5B). Each of the bit storage units 502-1 to 502-8 can be coupled to a corresponding CAM in the CAMs 412 through one of the CAM selection lines 504. In other words, the CAMs 412 and the shift register is connected through the CAM selection lines 504, and there is no data path connected between the CAMs 412 and the shift register. The CAM selector 502 can be configured to a row CAM of the CAMs 412 and enable data writing to that selected row CAM. For example, as shown in FIG. 5B, a logic value “1” in a bit storage unit of the CAM selector 502 selects a row CAM that is coupled to the bit storage unit and enables data writing to that row CAM, and a logic value “0” in a bit storage unit of the CAM selector 502 disables data writing to the row CAM coupled to the bit storage unit.

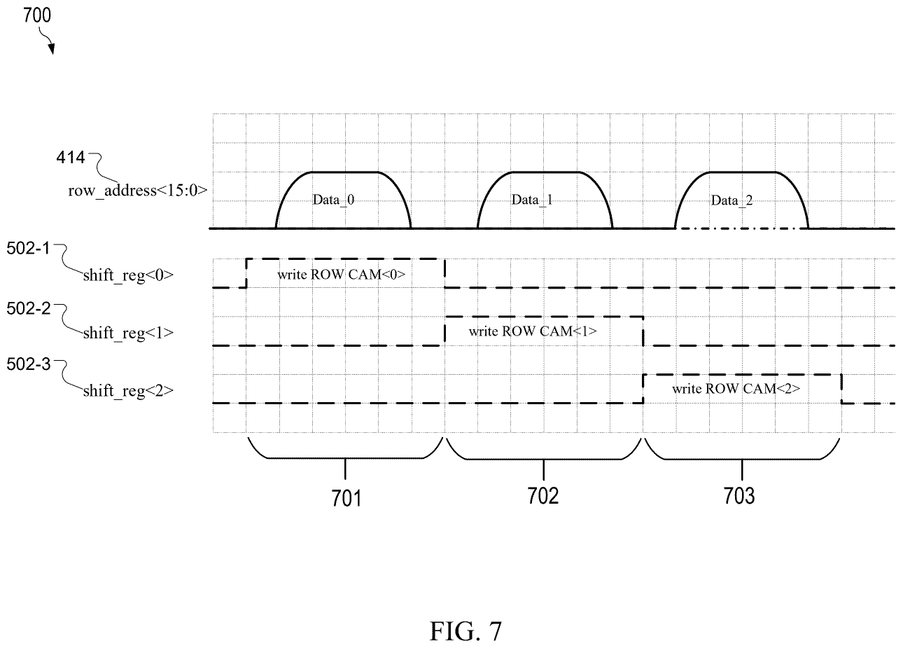

In some implementations (e.g., during the POR process of the DRAM device), the CAM selector 502 can select the row CAMs (e.g., CAM 0, CAM 1, . . . , CAM 7 as shown in FIG. 5B) in the CAMs 412 one by one. For example, the bit value “1” can be shifted from one bit storage unit of the CAM selector 502 to an adjacent bit storage unit. During the POR process of the DRAM device, the multiplexer 408 is configured to select the OTP device 506. In other words, the OTP device 506 is coupled to the CAMs 412 through the buffer 410 and the data path 414. The defective row addresses stored in the OTP device 506 can be loaded to the row CAMs (e.g., the current row CAM selected by the CAM selector 502) of the CAMs 412 in sequence. Data loading to the CAMs 412 is described below in further detail in reference to FIG. 7.

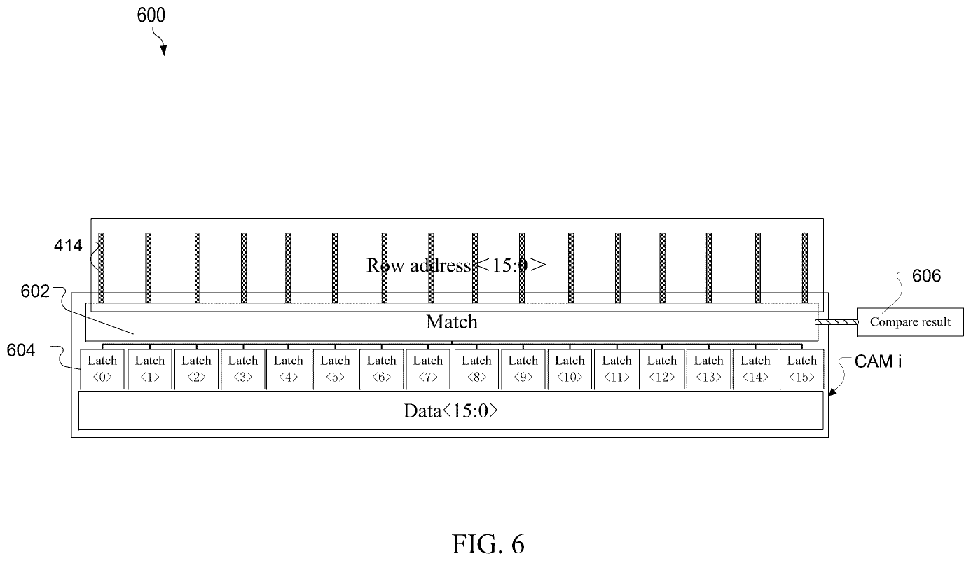

In some implementations, for example, after the POR process of the DRAM device, the multiplexer 408 is configured to select the CA interface 402 (e.g., through the control circuit 508 coupled to the CA interface 402). When the buffer circuit 406 receives a row address from the CA interface 402, the CAMs 412 can compare the received row address to data (e.g., the defective row addresses loaded to the CAMs 412 during the POR process) stored in each of the row CAMs (e.g., CAM 0, CAM 1, . . . , CAM 7) of the CAMs 412. A comparison result can be generated, for example, by a match circuit of the CAMs 412 as described below in further detail in reference to FIG. 6. In other words, in response to receiving an address from the CA interface 402, the match circuit (as shown in FIG. 6) is configured to compare the received address to the data loaded to the CAMs 412 and generate a comparison result.

FIG. 6 is a schematic diagram 600 illustrating an example row CAM coupled to a data path. The row CAM can be any of the row CAM (e.g., CAM i (0≤i≤7)) of the CAMs 412 of FIGS. 4 and 5. The data path can be an implementation of the data path 414 of FIGS. 4 and 5. As shown in FIG. 6, CAM i can include a match circuit 602 coupled to the data path 414 and multiple latches 604 coupled to the match circuit 602. The match circuit 602 can include multiple comparator circuits, and each comparator circuit can be configured to compare data carried in one of the data lines in the data path 414 and data stored in a corresponding latch 604. The match circuit 602 can be configured to output a comparison result 606. For example, the comparison result 606 can be a logic value “1” (e.g., a higher voltage) when a bit value stored in each latch 604 is equal to a bit value carried by a corresponding data line of the data path 414. In some implementations, the match circuit 602 can be located outside of the CAM i. For example, the match circuit 602 can be coupled between the data path 414 and the CAM i (e.g., the latches 604 of the CAM i). In some implementations, for example, during the POR process, the peripheral circuit can be configured to write data from the data path 414 to the CAM i. In this scenario, the data path 414 can be connected to the CAM i. In other words, in this example, the match circuit 602 can be bypassed, or the comparison result 606 is to be ignored.

While in FIGS. 5 and 6, the data path 414 include 16 data lines and the CAMs 412 includes 8 row CAMs, it is understood that these examples are for illustration purpose. In practice, the data path 414 and the row CAMs of the CAMs 412 can have any suitable bandwidth (e.g., 24-bit or 32-bit), and the CAMs 412 can have any suitable number of row CAMs.

FIG. 7 is a schematic timing diagram 700 showing an example method of writing data to the CAMs 412 of FIG. 4. The method of FIG. 7 can be performed by a peripheral circuit (e.g., the peripheral circuit 202, 400, or 500b) during a POR process of a DRAM device. The timing diagram 700 includes signals carried in the data path 414 and bit storage units 502-1 to 502-3 of the CAM selector 502. During this POR process, the multiplexer 408 is configured to select the OTP memory 506. The data path 414 is configured to transmit data from the OTP memory 506 to the CAMs 412.

As shown in FIG. 7, in time period 701, the bit storage unit 502-1 outputs a logic value “1” (e.g., a higher voltage level). Thus, a corresponding row CAM (e.g., CAM 0 of FIG. 5B) of the CAMs 412 is selected, and data writing to the selected row CAM is enabled. The peripheral circuit is configured to load data (e.g., data 0 as shown in FIG. 7) from the OTP memory 506 to CAM 0. For example, an address (e.g., a defective word line address) stored in the OTP memory 506 can be loaded from the OTP memory 506 and written to CAM 0. In period 701, other bit storage units (e.g., 502-2 and 502-3) output logic value “0.” As such, data writing to CAM 1, CAM 2, . . . , CAM 7 of the CAMs 412 is disabled.

After the data is loaded to CAM 0, in time period 702, the bit storage unit 502-1 can output a logic value “0” to disable data writing to CAM 0. In time period 702, the bit storage unit 502-2 can output a logic value “1” to enable data writing to CAM 1. The bit storage units 502-3 to 502-8 output logic values “0.” Thus, data writing to CAM 2, CAM 3, . . . , CAM 7 is also disabled. In time period 702, the peripheral circuit is configured to load data from the OTP memory 506 to CAM 1. For example, another defective word line address (e.g., data 1 as shown in FIG. 7) stored in the OTP memory 506 can be loaded from the OTP memory 506 and written to CAM 1.

Similarly, after the data 1 is loaded to CAM 1, in time period 703, the bit storage unit 502-3 can output a logic value “1” to enable data writing to CAM 2, and the bit storage units 502-1, 502-2, 502-4, . . . , 502-8 can output a logic value “0” to disable data writing to CAM 0, CAM 1, CAM 3, . . . , CAM 7. In time period 703, the peripheral circuit can be configured to load data 2 (e.g., another defective word line address) from the OTP memory 506 to CAM 2. The peripheral circuit can be configured to continue the above process and enable the row CAMs of the CAMs 412 in turn until the defective word line addresses stored in the OTP memory 506 are loaded to the CAMs 412 (or until the CAMs 412 is full).

While FIG. 7 illustrates that data can be written from the OTP memory 506 to the CAMs 412, it is understood that this example is for illustration purpose and is not intended to be construed in a limiting sense. In practice, with suitable support of communication protocols, data can also be written from the CA interface 402 to the CAMs 412. For example, the peripheral circuit can be configured to load data from the CA interface 402 to the CAMs 412, even after the POR process.

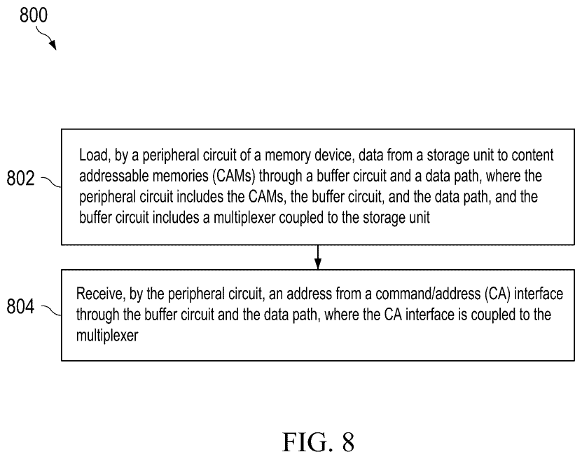

FIG. 8 is a flow chart of an example process 800 of operating a memory device. The process 800 can be performed by any suitable device or system as described herein, for example, according to the example techniques described with respect to FIGS. 1-7. The memory device can be the memory device 104 of FIG. 1 or the memory device 200 of FIGS. 2-3. In some implementations, the memory device can be a DRAM device. The process 800 includes operations that can be performed with any suitable order and/or any combination. In some implementations, the process 800 can be performed by a peripheral circuit (e.g., the peripheral circuit 202, 400, or 500b) of the memory device.

At operation 802, the peripheral circuit can load data from a storage unit (e.g., the storage unit 404 of FIG. 4 or the OTP memory 506 of FIG. 5B) to CAMs (e.g., the CAMs 412 of FIG. 4) through a buffer circuit (e.g., the buffer circuit 406 of FIG. 4) and a data path (e.g., the data path 414 of FIGS. 4 and 5). The peripheral circuit includes the CAMs, the buffer circuit, and the data path. The buffer circuit includes a multiplexer (e.g., the multiplexer 408 of FIG. 4) coupled to the storage unit.

At operation 804, the peripheral circuit can receive an address from a CA interface (e.g., the CA interface 402 of FIGS. 4 and 5) through the buffer circuit and the data path. The CA interface is coupled to the multiplexer.

In some implementations, the process 800 further includes comparing the address to the data loaded to the CAMs (e.g., as described in reference to FIG. 6).

In some implementations, loading the data from the storage unit to the CAMs (e.g., as described in reference to FIG. 7) includes: controlling a shift register (e.g., the CAM selector 502 of FIG. 5B) coupled to the CAMs to enable writing of a first CAM (e.g., CAM 0) of the CAMs; loading a first portion (e.g., data 0 of FIG. 7) of the data from the storage unit to the first CAM; controlling the shift register to enable writing of a second CAM (e.g., CAM 1) of the CAMs; and loading a second portion (e.g., data 1 of FIG. 7) of the data from the storage unit to the second CAM.

In some implementations, loading the data from the storage unit to the CAMs includes controlling the multiplexer (e.g., the multiplexer 408 of FIG. 4) to select the storage unit and forward the data from the storage unit to the data path.

In some implementations, loading the data from the storage unit to the CAMs includes loading the data from the storage unit to the CAMs in a power on reset process of the memory device.

In some implementations, receiving the address from the CA interface includes controlling the multiplexer to select the CA interface and forward the address to the data path.

In some implementations, receiving the address from the CA interface includes receiving the address from the CA interface after a power on reset process of the memory device.

In some implementations, the storage unit is a one-time programmable (OTP) memory configured to store defective row addresses.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as glass, plastic, or sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A memory device, comprising:
a memory array comprising memory banks; and
a peripheral circuit coupled to the memory array, the peripheral circuit comprising:
content addressable memories (CAMs);
a data path; and
a buffer circuit coupled to the CAMs through the data path, wherein the buffer circuit comprises a multiplexer coupled to a storage unit and a command/address (CA) interface, and the multiplexer is configured to select either the storage unit or the CA interface.

2. The memory device of claim 1, wherein the buffer circuit further comprises a buffer coupled between the data path and the multiplexer, and the multiplexer comprises a first input coupled to the CA interface, a second input coupled to the storage unit, and an output coupled to the buffer.

3. The memory device of claim 1, wherein the multiplexer is coupled to the CA interface through a control circuit, and the control circuit comprises an address and bank decoder and a control logic comprising a command decoder.

4. The memory device of claim 1, wherein the storage unit is a one-time programmable (OTP) memory configured to store defective row addresses.

5. The memory device of claim 1, wherein the CAMs are in a row address decoder of the peripheral circuit.

6. The memory device of claim 1, wherein the peripheral circuit further comprises a shift register coupled to the CAMs.

7. The memory device of claim 6, wherein the shift register comprises multiple bit storage units, each of the multiple bit storage units is coupled to a respective CAM of the CAMs and is configured to enable writing data into the respective CAM.

8. The memory device of claim 6, wherein the CAMs are coupled to the shift register through CAM selection lines.

9. The memory device of claim 1, wherein the memory device is a dynamic random access memory (DRAM) device, and at least one memory bank of the memory banks comprises DRAM cells.

10. The memory device of claim 1, wherein the peripheral circuit is configured to:
load data from the storage unit to the CAMs in a power on reset process of the memory device.

11. The memory device of claim 10, wherein the peripheral circuit further comprises a match circuit coupled between the data path and the CAMs, and the match circuit comprises comparator circuits and is configured to:
in response to receiving an address from the CA interface, compare the address to the data loaded to the CAMs and generate a comparison result.

12. A method of operating a memory device, comprising:
loading, by a peripheral circuit of the memory device, data from a storage unit to content addressable memories (CAMs) through a buffer circuit and a data path, wherein the peripheral circuit comprises the CAMs, the buffer circuit, and the data path, and the buffer circuit comprises a multiplexer coupled to the storage unit; and
receiving, by the peripheral circuit, an address from a command/address (CA) interface through the buffer circuit and the data path, wherein the CA interface is coupled to the multiplexer.

13. The method of claim 12, further comprising:
comparing the address to the data loaded to the CAMs.

14. The method of claim 12, wherein loading the data from the storage unit to the CAMs comprises:
controlling a shift register coupled to the CAMs to enable writing of a first CAM of the CAMs;
loading a first portion of the data from the storage unit to the first CAM;
controlling the shift register to enable writing of a second CAM of the CAMs; and
loading a second portion of the data from the storage unit to the second CAM.

15. The method of claim 12, wherein loading the data from the storage unit to the CAMs comprises:
controlling the multiplexer to select the storage unit and forward the data from the storage unit to the data path.

16. The method of claim 12, wherein loading the data from the storage unit to the CAMs comprises:
loading the data from the storage unit to the CAMs in a power on reset process of the memory device.

17. The method of claim 12, wherein receiving the address from the CA interface comprises:
controlling the multiplexer to select the CA interface and forward the address to the data path.

18. The method of claim 12, wherein receiving the address from the CA interface comprises:
receiving the address from the CA interface after a power on reset process of the memory device.

19. The method of claim 12, wherein the storage unit is a one-time programmable (OTP) memory configured to store defective row addresses.

20. A memory system, comprising a memory device and a memory controller coupled to the memory device, wherein the memory device comprises:
a memory array comprising memory banks; and
a peripheral circuit coupled to the memory array, the peripheral circuit comprising:
content addressable memories (CAMs);
a data path; and
a buffer circuit coupled to the CAMs through the data path, wherein the buffer circuit comprises a multiplexer coupled to a storage unit and a command/address (CA) interface, and the multiplexer is configured to select either the storage unit or the CA interface.
